(19) United States
(12) Patent Application Publication
(10) Pub. No.: US 2026/0247643 A1
(43) Pub. Date: Aug. 20, 2026

(54) SEMICONDUCTOR DEVICE

(71) Applicant: SAMSUNG ELECTRONICS CO., LTD., Suwon-si (KR)

(72) Inventors: Jea Won Lee, Suwon-si (KR); Seok Jun Won, Suwon-si (KR); Gwang Wook Lee, Suwon-si (KR); Wook Hyun Jo, Suwon-si (KR)

(21) Appl. No.: 19/292,494

(22) Filed: Aug. 6, 2025

(30) Foreign Application Priority Data
Feb. 14, 2025 (KR) 10-2025-0019728

(51) Int. Cl. H10D 10/60

(52) U.S. Cl. CPC H10D 10/60

(57) ABSTRACT

A semiconductor device includes a field insulating film including a first surface and a second surface opposite to each other in a first direction, a first epitaxial pattern structure disposed on the first surface of the field insulating film and having a first conductivity type, a second epitaxial pattern structure spaced apart from the first epitaxial pattern structure in a second direction perpendicular to the first direction and having the first conductivity type, a third epitaxial pattern structure disposed between the first epitaxial pattern structure and the second epitaxial pattern structure and having a second conductivity type different from the first conductivity type, a first contact connected to the first epitaxial pattern structure, a second contact connected to the second epitaxial pattern structure, and a third contact connected to the third epitaxial pattern structure, wherein the third epitaxial pattern structure is in contact with the first epitaxial pattern structure and the second epitaxial pattern structure.

### CROSS-REFERENCE TO RELATED APPLICATION

This application claims priority from Korean Patent Application No. 10-2025-0019728 filed on Feb. 14, 2025, in the Korean Intellectual Property Office, the contents of which are herein incorporated by reference in their entirety.

### BACKGROUND

A semiconductor device includes an integrated circuit including a MOS field effect transistor (a MOS (Metal Oxide Semiconductor) FET). As a size and a design rule of the semiconductor device are gradually reduced, a scale down of the MOS field effect transistor is also gradually accelerated. As the size of the MOS field effect transistor decreases, the operating characteristics of the semiconductor device may be deteriorated. Accordingly, various methods for forming a semiconductor device with better performance while overcoming limitations due to high integration of the semiconductor device have been studied.

In one example, for the high integration of the semiconductor device, a fin field effect transistor or a multi-bridge channel field effect transistor using a three-dimensional channel has been used, and in addition, a structure of a bipolar junction transistor compatible with the field effect transistor using the three-dimensional channel has been proposed.

### SUMMARY

Some aspects of the present disclosure provide semiconductor devices with improved operating characteristics and reliability. The technical advantages provided by of the present disclosure are not limited to these aspects, and others may be clearly understood by those skilled in the art from the following description.

According to some implementations of the present disclosure, there is provided a semiconductor device comprising a field insulating film including a first surface and a second surface opposite to each other in a first direction, a first epitaxial pattern structure disposed on the first surface of the field insulating film and having a first conductivity type, a second epitaxial pattern structure spaced apart from the first epitaxial pattern structure in a second direction perpendicular to the first direction and having the first conductivity type, a third epitaxial pattern structure disposed between the first epitaxial pattern structure and the second epitaxial pattern structure and having a second conductivity type different from the first conductivity type, a first contact connected to the first epitaxial pattern structure, a second contact connected to the second epitaxial pattern structure, and a third contact connected to the third epitaxial pattern structure, wherein the third epitaxial pattern structure is in contact with the first epitaxial pattern structure and the second epitaxial pattern structure.

According to some implementations of the present disclosure, there is provided a semiconductor device comprising a field insulating film including a first surface and a second surface opposite to each other in a first direction, a first epitaxial pattern structure disposed on the first surface of the field insulating film and having a first conductivity type, a second epitaxial pattern structure spaced apart from the first epitaxial pattern structure in a second direction perpendicular to the first direction and having the first conductivity type, a third epitaxial pattern structure disposed between the first epitaxial pattern structure and the second epitaxial pattern structure and having a second conductivity type different from the first conductivity type, a first contact connected to the first epitaxial pattern structure, a second contact connected to the second epitaxial pattern structure, and a third contact connected to the third epitaxial pattern structure, wherein each of the first to third epitaxial pattern structures includes a fin-shaped pattern portion and an epitaxially-grown portion, wherein the fin-shaped pattern portion of the third epitaxial pattern structure is spaced apart from the fin-shaped pattern portion of the first epitaxial pattern structure and the fin-shaped pattern portion of the second epitaxial pattern structure in the second direction, wherein the epitaxially-grown portion of the third epitaxial pattern structure is in contact with the epitaxially-grown portion of the first epitaxial pattern structure and the epitaxially-grown portion of the second epitaxial pattern structure.

According to some implementations of the present disclosure, there is provided a semiconductor device comprising a back wiring line including a first surface and a second surface opposite to each other in a first direction, a first epitaxial pattern structure disposed on the first surface of the back wiring line and having a first conductivity type, a second epitaxial pattern structure spaced apart from the first epitaxial pattern structure in a second direction perpendicular to the first direction and having the first conductivity type, a third epitaxial pattern structure disposed between the first epitaxial pattern structure and the second epitaxial pattern structure and having a second conductivity type different from the first conductivity type, a field insulating film disposed between the back wiring line and the first epitaxial pattern structure, a first contact disposed in the field insulating film and connected to the first epitaxial pattern structure, a second contact disposed in the field insulating film and connected to the second epitaxial pattern structure, and a third contact disposed in the field insulating film and connected to the third epitaxial pattern structure, wherein the third epitaxial pattern structure is in contact with the first epitaxial pattern structure and the second epitaxial pattern structure.

### BRIEF DESCRIPTION OF DRAWINGS

FIG. 1 is a plan view illustrating an example of a semiconductor device.

FIG. 2 is a cross-sectional view taken along a line A-A of FIG. 1.

FIG. 3 is a cross-sectional view taken along a line B-B of FIG. 1.

FIGS. 4 and 5 are cross-sectional diagrams illustrating examples of semiconductor devices.

FIGS. 6 and 7 are plan and cross-sectional diagrams, respectively, illustrating an example of a semiconductor device,

FIG. 8 is a plan view illustrating an example of a semiconductor device.

FIG. 9 is a graph illustrating examples of impurity concentrations.

FIGS. 10 and 11 are cross-sectional diagrams illustrating an example of a semiconductor device,

FIG. 12 is a cross-sectional diagram illustrating an example of a semiconductor device.

FIG. 13 is a cross-sectional diagram illustrating an example of a semiconductor device.

FIGS. 14 to 16 are diagrams illustrating an example of a semiconductor device.

FIG. 17 is a cross-sectional diagram illustrating an example of a semiconductor device.

FIG. 18 is a cross-sectional diagram illustrating an example of a semiconductor device.

FIG. 19 is a cross-sectional diagram illustrating an example of a semiconductor device.

FIGS. 20 to 22 are diagrams illustrating an example of a semiconductor device.

FIGS. 23 to 25 are diagrams illustrating an example of a semiconductor device.

FIGS. 26 and 27 are cross-sectional diagrams illustrating an example of a semiconductor device.

### DETAILED DESCRIPTIONS

As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these terms are used to distinguish one element, component, region, layer or section from another element, component, region, layer or section, without implying any particular ordering or arrangement, unless indicated otherwise by context. Thus, a first element, component, region, layer or section described below could be termed a second element, component, region, layer or section, without departing from the spirit and scope of the present disclosure.

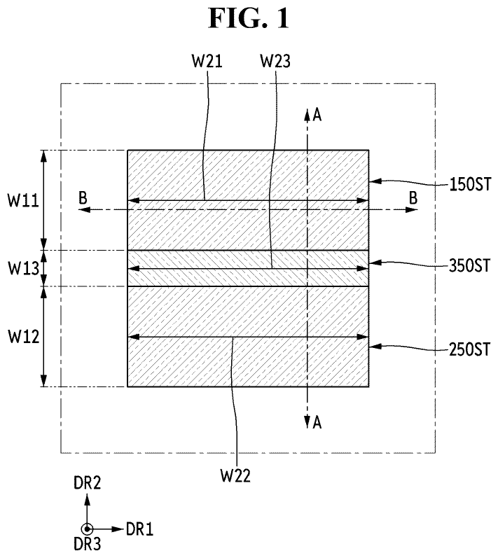

An example of a semiconductor device will be described with reference to FIGS. 1 to 3.

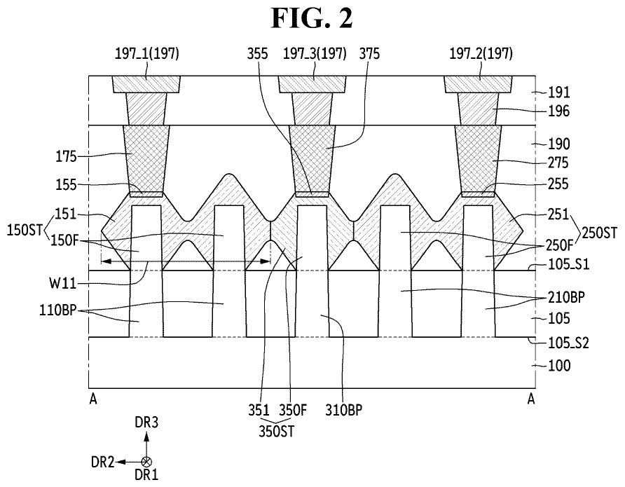

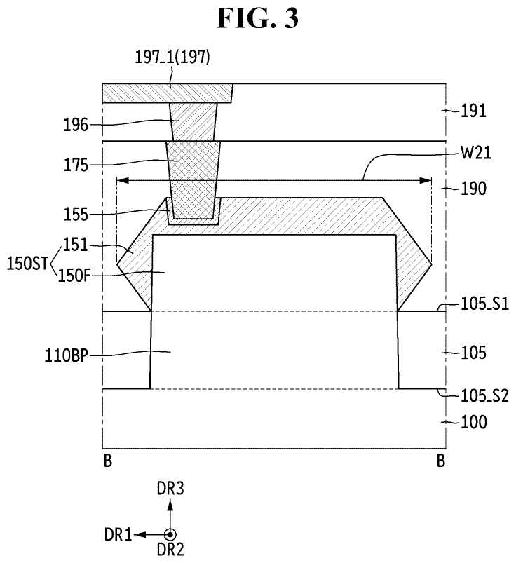

FIG. 1 is a plan view illustrating the semiconductor device. FIG. 2 is a cross-sectional view taken along a line A-A of FIG. 1. FIG. 3 is a cross-sectional view taken along a line B-B of FIG. 1.

For reference, FIG. 1 schematically illustrates the semiconductor device except for a connection contact 175, 275, and 375 and a front wiring line 197.

Referring to FIGS. 1 to 3, the semiconductor device may include a field insulating film 105, a first epitaxial pattern structure 150ST, a second epitaxial pattern structure 250ST, a third epitaxial pattern structure 350ST, a first front connection contact 175, a second front connection contact 275, a third front connection contact 375, and a front wiring line 197.

The substrate 100 may be made of bulk silicon or silicon-on-insulator (SOI). As another example, the substrate 100 may be a silicon substrate, or may include a material other than silicon, for example, silicon germanium, silicon germanium on insulator (SGOI), indium antimonide, lead telluride compound, indium arsenide, indium phosphide, gallium arsenide, or gallium antimonide. However, the substrate type is not limited thereto.

The field insulating film 105 may be disposed on the substrate 100. The field insulating film 105 may include a first surface 105_S1 and a second surface 105_S2 opposite to each other in a third direction DR3. The second surface 105_S2 of the field insulating film may face the substrate 100.

The field insulating film 105 may include, for example, but is not limited to, silicon oxide, silicon nitride, silicon oxynitride, or a combination thereof. Although the field insulating film 105 is illustrated as a single film, this is intended only for convenience of illustration, and the field insulating film 105 may include multiple distinct films.

The first epitaxial pattern structure 150ST may be disposed on the field insulating film 105. For example, the first epitaxial pattern structure 150ST may be disposed on the first surface 105_S1 of the field insulating film.

The field insulating film 105 may be disposed between the substrate 100 and the first epitaxial pattern structure 150ST. At least a portion of the first epitaxial pattern structure 150ST may protrude in the third direction DR3 from the first surface 105_S1 of the field insulating film.

The second epitaxial pattern structure 250ST may be disposed on the field insulating film 105. For example, the second epitaxial pattern structure 250ST may be disposed on the first surface 105_S1 of the field insulating film. The second epitaxial pattern structure 250ST may be spaced apart from the first epitaxial pattern structure 150ST in a second direction DR2.

The field insulating film 105 may be disposed between the substrate 100 and the second epitaxial pattern structure 250ST. At least a portion of the second epitaxial pattern structure 250ST may protrude in the third direction DR3 from the first surface 105_S1 of the field insulating film.

The third epitaxial pattern structure 350ST may be disposed on the field insulating film 105. For example, the third epitaxial pattern structure 350ST may be disposed on the first surface 105_S1 of the field insulating film. The third epitaxial pattern structure 350ST may be disposed between the first epitaxial pattern structure 150ST and the second epitaxial pattern structure 250ST.

The third epitaxial pattern structure 350ST is in contact with the first epitaxial pattern structure 150ST and the second epitaxial pattern structure 250ST. The third epitaxial pattern structure 350ST may be directly connected to the first epitaxial pattern structure 150ST and the second epitaxial pattern structure 250ST.

The field insulating film 105 may be disposed between the substrate 100 and the third epitaxial pattern structure 350ST. At least a portion of the third epitaxial pattern structure 350ST may protrude in the third direction DR3 from the first surface 105_S1 of the field insulating film.

Each of the first epitaxial pattern structure 150ST and the second epitaxial pattern structure 250ST may have a first conductivity type. The third epitaxial pattern structure 350ST may have a second conductivity type different from the first conductivity type. For example, each of the first epitaxial pattern structure 150ST and the second epitaxial pattern structure 250ST may contain impurities having a first conductivity type. The third epitaxial pattern structure 350ST may contain impurities having the second conductivity type.

In some implementations, the first conductivity type may be a P-type, and the second conductivity type may be an N-type. For example, each of the first epitaxial pattern structure 150ST and the second epitaxial pattern structure 250ST may contain p-type impurities, and the third epitaxial pattern structure 350ST may contain n-type impurities.

In some implementations, the first conductivity type may be N-type, and the second conductivity type may be P-type. For example, each of the first epitaxial pattern structure 150ST and the second epitaxial pattern structure 250ST may contain n-type impurities, and the third epitaxial pattern structure 350ST may contain p-type impurities.

The first epitaxial pattern structure 150ST and the third epitaxial pattern structure 350ST may be in contact with each other to form a PN junction. The second epitaxial pattern structure 250ST and the third epitaxial pattern structure 350ST may be in contact with each other to form a PN junction.

The third epitaxial pattern structure 350ST may be a base area of a bipolar junction transistor BJT. One of the first epitaxial pattern structure 150ST and the second epitaxial pattern structure 250ST may be a collector area of the bipolar junction transistor BJT, and the other thereof may be an emitter area of the bipolar junction transistor BJT.

Hereinafter, an example in which the first epitaxial pattern structure 150ST is an emitter area of the bipolar junction transistor BJT, and the second epitaxial pattern structure 250ST is a collector area of the bipolar junction transistor BJT will be described. However, the configuration is not limited thereto.

For example, the p-type impurity may include at least one of boron (B) or gallium (Ga). The n-type impurity may include at least one of phosphorus (P), arsenic (As), antimony (Sb), or bismuth (Bi). When each of the first epitaxial pattern structure 150ST and the second epitaxial pattern structure 250ST contains the p-type impurities, the p-type impurities contained in the first epitaxial pattern structure 150ST and the p-type impurities contained in the second epitaxial pattern structure 250ST may be the same as or different from each other. When each of the first epitaxial pattern structure 150ST and the second epitaxial pattern structure 250ST contains the n-type impurities, the n-type impurities contained in the first epitaxial pattern structure 150ST and the n-type impurities contained in the second epitaxial pattern structure 250ST may be the same as or different from each other.

In some implementations, a width W11 in the second direction DR2 of the first epitaxial pattern structure 150ST may be greater than a width W13 in the second direction DR2 of the third epitaxial pattern structure 350ST. A width W12 in the second direction DR2 of the second epitaxial pattern structure 250ST may be greater than the width W13 in the second direction DR2 of the third epitaxial pattern structure 350ST.

A width W21 in a first direction DR1 of the first epitaxial pattern structure 150ST may be equal to a width W23 in the first direction DR1 of the third epitaxial pattern structure 350ST. However, the widths are not limited thereto. A width W22 in the first direction DR1 of the second epitaxial pattern structure 250ST may be equal to the width W23 in the first direction DR1 of the third epitaxial pattern structure 350ST. However, the widths are not limited thereto.

The first epitaxial pattern structure 150ST may include a first epitaxially-grown portion 151 and a plurality of first fin-shaped pattern portions 150F. Each of the first epitaxially-grown portion 151 and the first fin-shaped pattern portion 150F may be a portion doped with impurities having the first conductivity type. Although the first epitaxial pattern structure 150ST is illustrated as including two first fin-shaped pattern portions 150F, this is intended only for convenience of illustration, and the number of fins is not limited thereto.

The first epitaxially-grown portion 151 may be disposed on a sidewall of the first fin-shaped pattern portion 150F. The first epitaxially-grown portion 151 may be disposed on an upper surface of the first fin-shaped pattern portion 150F. The first epitaxially-grown portion 151 is in contact with each first fin-shaped pattern portion 150F. The first epitaxially-grown portion 151 may be directly connected to each of the first fin-shaped pattern portions 150F.

The second epitaxial pattern structure 250ST may include a second epitaxially-grown portion 251 and a plurality of second fin-shaped pattern portions 250F. Each of the second epitaxially-grown portion 251 and the second fin-shaped pattern portion 250F may be a portion doped with impurities having the first conductivity type. Although the second epitaxial pattern structure 250ST is illustrated as including two second fin-shaped pattern portions 250F, this is intended only for convenience of illustration, and the fin number is not limited thereto.

The second epitaxially-grown portion 251 may be disposed on a sidewall of the second fin-shaped pattern portion 250F. The second epitaxially-grown portion 251 may be disposed on an upper surface of the second fin-shaped pattern portion 250F. The second epitaxially-grown portion 251 is in contact with each second fin-shaped pattern portion 250F. The second epitaxially-grown portion 251 may be directly connected to each second fin-shaped pattern portion 250F.

The third epitaxial pattern structure 350ST may include a third epitaxially-grown portion 351 and at least one third fin-shaped pattern portion 350F. Each of the third epitaxially-grown portion 351 and the third fin-shaped pattern portion 350F may be a portion doped with impurities having the second conductivity type. Although the third epitaxial pattern structure 350ST is illustrated as including one third fin-shaped pattern portion 350F, this is intended only for convenience of illustration, and the fin number not limited thereto. For example, multiple third fin-shaped pattern portions 350F may be included.

The third epitaxially-grown portion 351 may be disposed on a sidewall of the third fin-shaped pattern portion 350F. The third epitaxially-grown portion 351 may be disposed on an upper surface of the third fin-shaped pattern portion 350F. The third epitaxially-grown portion 351 may be in contact with each third fin-shaped pattern portion 350F. The third epitaxially-grown portion 351 may be directly connected to each third fin-shaped pattern portion 350F.

Each of the second fin-shaped pattern portion 250F and the third fin-shaped pattern portion 350F is spaced apart from the first fin-shaped pattern portion 150F in the second direction DR2. The second fin-shaped pattern portion 250F is spaced apart from the third fin-shaped pattern portion 350F in the second direction DR2. The third fin-shaped pattern portion 350F may be disposed between the first fin-shaped pattern portion 150F and the second fin-shaped pattern portion 250F.

In the semiconductor device, the number of first fin-shaped pattern portions 150F included in the first epitaxial pattern structure 150ST may be greater than the number of third fin-shaped pattern portions 350F included in the third epitaxial pattern structure 350ST. The number of second fin-shaped pattern portions 250F included in the second epitaxial pattern structure 250ST may be greater than the number of third fin-shaped pattern portions 350F included in the third epitaxial pattern structure 350ST.

The second epitaxially-grown portion 251 may be spaced apart from the first epitaxially-grown portion 151 in the second direction DR2. The third epitaxially-grown portion 351 may be disposed between the first epitaxially-grown portion 151 and the second epitaxially-grown portion 251. The third epitaxially-grown portion 351 may contact the first epitaxially-grown portion 151 and the second epitaxially-grown portion 251. The third epitaxially-grown portion 351 may be directly connected to the first epitaxially-grown portion 151 and the second epitaxially-grown portion 251. The third epitaxial pattern structure 350ST may be connected to the first epitaxial pattern structure 150ST and the second epitaxial pattern structure 250ST using the third epitaxially-grown portion 351.

Each of the first fin-shaped pattern portion 150F, the second fin-shaped pattern portion 250F, and the third fin-shaped pattern portion 350F may include silicon or germanium, which is an elemental semiconductor material. In addition, each of the first fin-shaped pattern portion 150F, the second fin-shaped pattern portion 250F, and the third fin-shaped pattern portion 350F may include a compound semiconductor, and may include, for example, a group IV-IV compound semiconductor or a group III-V compound semiconductor.

The group IV-IV compound semiconductor may include, for example, a binary compound including two of carbon (C), silicon (Si), germanium (Ge), and tin (Sn), a ternary compound including three thereof, or a compound obtained by doping a group IV element thereto.

The group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with each other, a ternary compound obtained by combining two of aluminum (Al), gallium (Ga), and indium (In) as a group III element and one of phosphorus (P), arsenic (As), and antimony (Sb) as a group V with each other, or a quaternary compound obtained by combining three of aluminum (Al), gallium (Ga), and indium (In) as a group III element and one of phosphorus (P), arsenic (As), and antimony (Sb) as a group V with each other.

Each of the first epitaxially-grown portion 151, the second epitaxially-grown portion 251, and the third epitaxially-grown portion 351 may include, for example, silicon or germanium, which is an elemental semiconductor material. In addition, each of the first epitaxially-grown portion 151, the second epitaxially-grown portion 251, and the third epitaxially-grown portion 351 may include, for example, a binary compound including two of carbon (C), silicon (Si), germanium (Ge), and tin (Sn), a ternary compound including three thereof, or a compound obtained by doping a group IV element thereto.

Although each of the first fin-shaped pattern portion 150F, the second fin-shaped pattern portion 250F, and the third fin-shaped pattern portion 350F is illustrated as protruding in the third direction DR3 beyond the first surface 105_S1 of the field insulating film, this is intended only for convenience of illustration, and the arrangement is not limited thereto.

A first lower pattern 110BP may protrude from the substrate 100 in the third direction DR3. The first lower pattern 110BP may extend in the first direction DR1. The first lower pattern 110BP may include a long side extending in the first direction DR1 and a short side extending in the second direction DR2.

A second lower pattern 210BP may protrude from the substrate 100 in the third direction DR3. The second lower pattern 210BP may extend in the first direction DR1. The second lower pattern 210BP may be spaced apart from the first lower pattern 110BP in the second direction DR2.

A third lower pattern 310BP may protrude from the substrate 100 in the third direction DR3. Although not shown, the third lower pattern 310BP may extend in the first direction DR. 1. The third lower pattern 310BP may be disposed between the first lower pattern 110BP and the second lower pattern 210BP.

The field insulating film 105 may cover a sidewall of the first lower pattern 110BP, a sidewall of the second lower pattern 210BP, and a sidewall of the third lower pattern 310BP.

The first lower pattern 110BP is in contact with the first epitaxial pattern structure 150ST. The first lower pattern 110BP may be directly connected to the first epitaxial pattern structure 150ST. For example, the first lower pattern 110BP may be directly connected to the first fin-shaped pattern portion 150F. Each of the first fin-shaped pattern portions 150F may be directly connected to each first lower pattern 110BP. A portion of a fin-shaped pattern protruding from the substrate 100 may become the first lower pattern 110BP, and a remaining portion thereof may become the first fin-shaped pattern portion 150F.

The second lower pattern 210BP is in contact with the second epitaxial pattern structure 250ST. The second lower pattern 210BP may be directly connected to the second epitaxial pattern structure 250ST. For example, the second lower pattern 210BP may be directly connected to the second fin-shaped pattern portion 250F. Each of the second fin-shaped pattern portions 250F may be directly connected to each second lower pattern 210BP.

The third lower pattern 310BP is in contact with the third epitaxial pattern structure 350ST. The third lower pattern 310BP may be directly connected to the third epitaxial pattern structure 350ST. For example, the third lower pattern 310BP may be directly connected to the third fin-shaped pattern portion 350F. Each of the third fin-shaped pattern portions 350F may be directly connected to each third lower pattern 310BP.

When the first lower pattern 110BP is doped with impurities having the first conductivity type, a boundary between the first lower pattern 110BP and the first fin-shaped pattern portion 150F may be defined based on a concentration gradient of impurities occurring between the first lower pattern 110BP and the first fin-shaped pattern portion 150F. When the second lower pattern 210BP is doped with an impurity having the first conductivity type, a boundary between the second lower pattern 210BP and the second fin-shaped pattern portion 250F may be defined based on a concentration gradient of the impurity occurring between the second lower pattern 210BP and the second fin-shaped pattern portion 250F. When the third lower pattern 310BP is doped with an impurity having the second conductivity type, a boundary between the third lower pattern 310BP and the third fin-shaped pattern portion 350F may be defined based on a concentration gradient of an impurity occurring between the third lower pattern 310BP and the third fin-shaped pattern portion 350F.

Each of the first lower pattern 110BP, the second lower pattern 210BP, and the third lower pattern 310BP may include one of silicon or germanium as an element semiconductor material, a Group IV-IV compound semiconductor, or a Group III-V compound semiconductor,.

A first interlayer insulating film 190 may be disposed on the first surface 105_S1 of the field insulating film. The first interlayer insulating film 190 may cover the first epitaxial pattern structure 150ST, the second epitaxial pattern structure 250ST, and the third epitaxial pattern structure 350ST.

The first interlayer insulating film 190 may include, for example, at least one of silicon oxide, silicon nitride, silicon oxynitride, and a low dielectric constant material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilyl Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped Silicon Oxide), OSG(Organo Silicate Glass), SiLK, Amorphous Fluorinated Carbon, silica aerogels, silica xerogels, mesoporous silica, or a combination thereof. However, the material(s) of the first interlayer insulating film 190, and examples of low-k materials, are not limited thereto.

An epitaxial pattern etch stop film may be disposed between the first interlayer insulating film 190 and the first epitaxial pattern structure 150ST, between the first interlayer insulating film 190 and the second epitaxial pattern structure 250ST, and between the first interlayer insulating film 190 and the third epitaxial pattern structure 350ST. The epitaxial pattern etch stop film may include a material having an etch selectivity with respect to the first interlayer insulating film 190. The epitaxial pattern etch stop film may include, for example, silicon nitride, silicon oxynitride, silicon oxycarbonitride, silicon boron nitride, silicon oxyboron nitride, silicon oxycarbide, or a combination thereof.

The first front connection contact 175 is disposed on the first epitaxial pattern structure 150ST. The first front connection contact 175 is connected to the first epitaxial pattern structure 150ST. The first front connection contact 175 may be disposed in the first interlayer insulating film 190.

The second front connection contact 275 is disposed on the second epitaxial pattern structure 250ST. The second front connection contact 275 is connected to the second epitaxial pattern structure 250ST. The second front connection contact 275 may be disposed in the first interlayer insulating film 190.

The third front connection contact 375 is disposed on the third epitaxial pattern structure 350ST. The third front connection contact 375 is connected to the third epitaxial pattern structure 350ST. The third front connection contact 375 may be disposed in the first interlayer insulating film 190.

The first front connection contact 175, the second front connection contact 275, and the third front connection contact 375 may be disposed on the first surface 105_S1 of the field insulating film. Although it is illustrated that each of the first front connection contact 175, the second front connection contact 275, and the third front connection contact 375 is embodied as a single film, this is intended only for convenience of illustration, and the contact configuration is not limited thereto. Each of the first front connection contact 175, the second front connection contact 275, and the third front connection contact 375 may include, for example, a metal, a conductive metal nitride, a conductive metal carbide, a conductive metal oxide, a conductive metal carbonitride, a two-dimensional (2D) material, or a combination thereof. The two-dimensional material may be a metallic material and/or a semiconductor material. The two-dimensional material (2D material) may include a two-dimensional allotrope or a two-dimensional compound, and may include, for example, at least one of graphene, molybdenum disulfide (MoS₂), molybdenum diselenide (MoSe₂), tungsten diselenide (WSe₂), and tungsten disulfide (WS₂). However, examples of two-dimensional materials are not limited thereto.

A first front contact silicide film 155 may be disposed between the first front connection contact 175 and the first epitaxial pattern structure 150ST. A second front contact silicide film 255 may be disposed between the second front connection contact 275 and the second epitaxial pattern structure 250ST. A third front contact silicide film 355 may be disposed between the third front connection contact 375 and the third epitaxial pattern structure 350ST. Each of the f irst front contact silicide film 155, the second front contact silicide film 255, and the third front contact silicide film 355 may include a metal silicide.

A second interlayer insulating film 191 is disposed on the first interlayer insulating film 190. The second interlayer insulating film 191 may include, for example, at least one of silicon oxide, silicon nitride, silicon oxynitride, or a low dielectric constant material.

A front wiring via 196 and a front wiring line 197 may be disposed in the second interlayer insulating film 191. The front wiring line 197 may include first to third front wiring lines 197_1, 197_2, and 197_3.

The first front wiring line 197_1 may be connected to the first front connection contact 175. The second front wiring line 197_2 may be connected to the second front connection contact 275. The third front wiring line 197_3 may be connected to the third front connection contact 375. The front wiring via 196 may connect the front wiring line 197 to the front connection contacts 175, 275, and 375.

Although the front wiring via 196 and the front wiring line 197 are illustrated as being distinguished from each other, this is intended only for convenience of illustration, and the via configuration is not limited thereto. That is, for example, after the front wiring via 196 has been formed, the front wiring line 197 may be formed. As another, the front wiring via 196 and the front wiring line 197 may be simultaneously formed or formed in a common process.

Although each of the front wiring via 196 and the front wiring line 197 is illustrated as being embodied as a single film, this is intended only for convenience of illustration, and the scope of the present disclosure is not limited thereto.

Each of the front wiring via 196 and the front wiring line 197 may include, for example, at least one of a metal, a conductive metal nitride, a conductive metal carbide, a conductive metal oxide, a conductive metal carbonitride, or a two-dimensional material (2D material).

A bipolar junction transistor (BJT) may be implemented using the epitaxial pattern structure disposed on the field insulating film 105, for example, without a well area (or an impurity-doped area) in which impurities are doped into the substrate 100. Accordingly, an area in which the bipolar junction transistor (BJT) is formed may be freely selected, and thus design flexibility and performance of the semiconductor device may be improved.

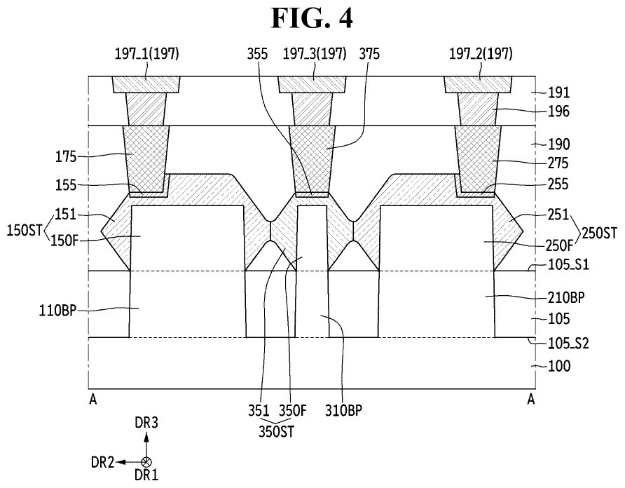

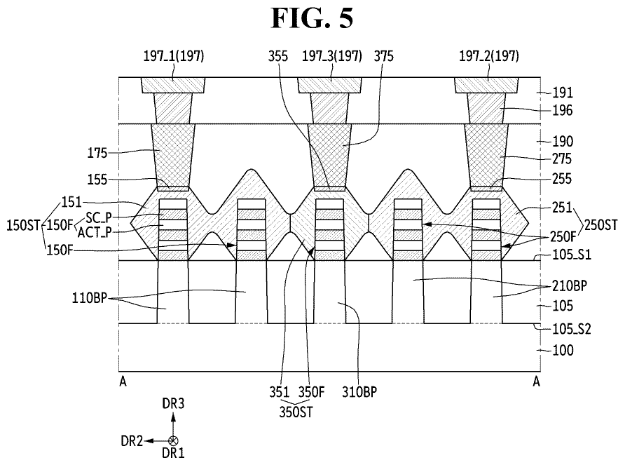

FIGS. 4 and 5 are diagrams illustrating examples of semiconductor devices. For convenience of description, differences thereof from those as described above with reference to FIGS. 1 to 3 will be mainly described.

Referring to FIG. 4, in some implementations, the number of third fin-shaped pattern portions 350F included in the third epitaxial pattern structure 350ST may be equal to the number of first fin-shaped pattern portions 150F included in the first epitaxial pattern structure 150ST, and may be equal to the number of second fin-shaped pattern portions 250F included in the second epitaxial pattern structure 250ST.

For example, each of the first epitaxial pattern structure 150ST, the second epitaxial pattern structure 250ST, and the third epitaxial pattern structure 350ST may include one fin-shaped pattern portion.

Referring to FIG. 5, in some implementations, each of the first fin-shaped pattern portion 150F, the second fin-shaped pattern portion 250F, and the third fin-shaped pattern portion 350F may include active patterns ACT_P and sacrificial patterns SC_P.

The active patterns ACT_P and the sacrificial patterns SC_P may be alternately laminated in the third direction DR3 while being disposed on the substrate 100. The active patterns ACT_P may be, for example, a portion used as a channel area of a metal-oxide-semiconductor field-effect transistor (MOSFET). The sacrificial patterns SC_P may be a portion removed in a process of forming the metal-oxide-semiconductor field-effect transistor (MOSFET).

The active pattern ACT_P and the sacrificial pattern SC_P may include semiconductor materials having an etch selectivity with respect to each other. The active pattern ACT_P may include, for example, a silicon film. However, the material is not limited thereto. The sacrificial pattern SC_P may include, for example, a silicon-germanium film. However, the material is not limited thereto.

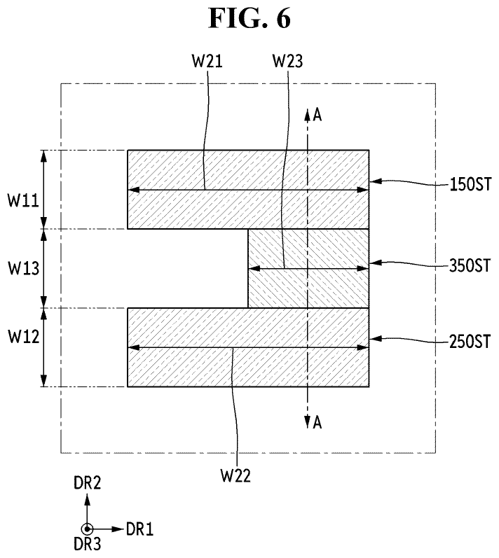

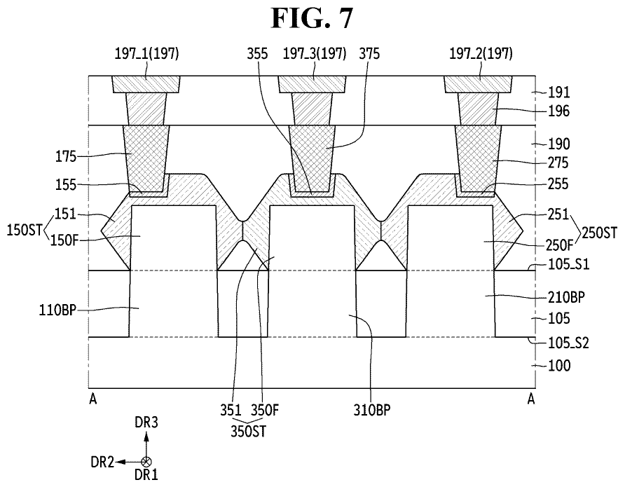

FIGS. 6 and 7 are diagrams illustrating an example of a semiconductor device. For convenience of description, differences thereof from those as described above with reference to FIGS. 1 to 3 will be mainly described.

For reference, FIG. 6 is a plan view illustrating a semiconductor device. FIG. 7 is a cross-sectional view taken along a line A-A of FIG. 6.

Referring to FIGS. 6 and 7, the width W21 in the first direction DR1 of the first epitaxial pattern structure 150ST may be different from the width W23 in the first direction DR1 of the third epitaxial pattern structure 350ST.

The width W22 in the first direction DR1 of the second epitaxial pattern structure 250ST may be different from the width W23 in the first direction DR1 of the third epitaxial pattern structure 350ST.

For example, the width W21 in the first direction DR1 of the first epitaxial pattern structure 150ST may be greater than the width W23 in the first direction DR1 of the third epitaxial pattern structure 350ST. The width W22 in the first direction DR1 of the second epitaxial pattern structure 250ST may be greater than the width W23 in the first direction DR1 of the third epitaxial pattern structure 350ST.

The width W11 in the second direction DR2 of the first epitaxial pattern structure 150ST may be equal to the width W13 in the second direction DR2 of the third epitaxial pattern structure 350ST. However, the width relationship is not limited thereto. The width W12 in the second direction DR2 of the second epitaxial pattern structure 250ST may be equal to the width W13 in the second direction DR2 of the third epitaxial pattern structure 350ST. However, the width relationship is not limited thereto.

The number of third fin pattern portions 350F included in the third epitaxial pattern structure 350ST may be equal to the number of first fin pattern portions 150F included in the first epitaxial pattern structure 150ST, and may be equal to the number of second fin pattern portions 250F included in the second epitaxial pattern structure 250ST. However, the numbers of fins are not limited thereto.

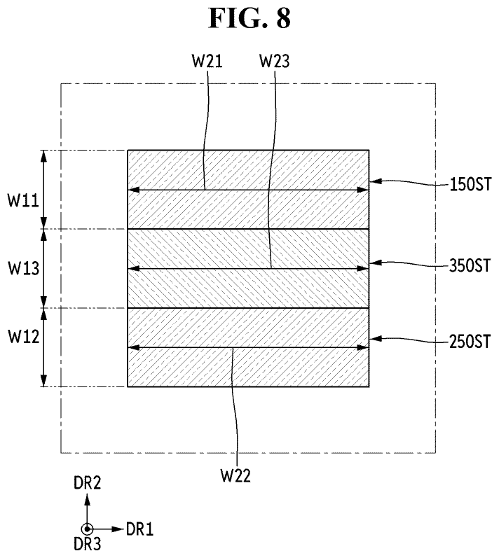

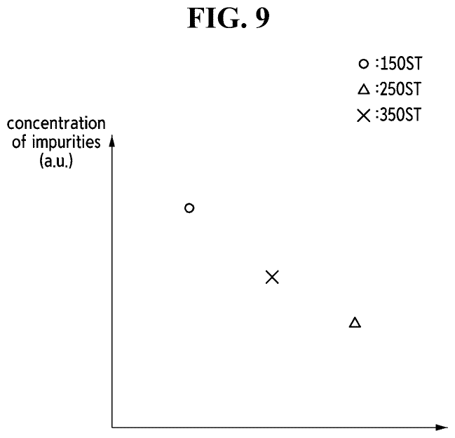

FIGS. 8 and 9 are diagrams illustrating an example of a semiconductor device. For convenience of description, differences thereof from those as described above with reference to FIGS. 1 to 3 will be mainly described.

For reference, FIG. 8 is a plan view illustrating an example of a semiconductor device. FIG. 9 is a diagram comparing respective concentrations of impurities respectively contained in the first to third epitaxial pattern structures of FIG. 8 with each other.

Referring to FIGS. 8 and 9, in some implementations, the concentration (/cm³) of the impurities of the first conductivity type contained in the first epitaxial pattern structure 150ST is greater than the concentration of the impurities of the second conductivity type contained in the third epitaxial pattern structure 350ST.

The concentration of the impurities of the first conductivity type contained in the second epitaxial pattern structure 250ST may be lower than the concentration of the impurities of the second conductivity type contained in the third epitaxial pattern structure 350ST.

The width W11 in the second direction DR2 of the first epitaxial pattern structure 150ST may be equal to the width W13 in the second direction DR2 of the third epitaxial pattern structure 350ST. However, the widths are not limited thereto. The width W12 in the second direction DR2 of the second epitaxial pattern structure 250ST may be equal to the width W13 in the second direction DR2 of the third epitaxial pattern structure 350ST. However, the widths are not limited thereto.

The width W21 in the first direction DR1 of the first epitaxial pattern structure 150ST may be equal to a width W23 in the first direction DR1 of the third epitaxial pattern structure 350ST. However, the widths are not limited thereto. The width W22 in the first direction DR1 of the second epitaxial pattern structure 250ST may be equal to the width W23 in the first direction DR1 of the third epitaxial pattern structure 350ST. However, the widths are not limited thereto.

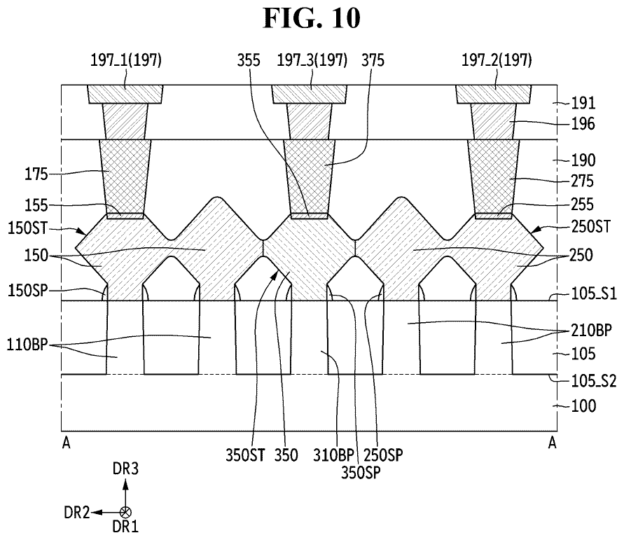

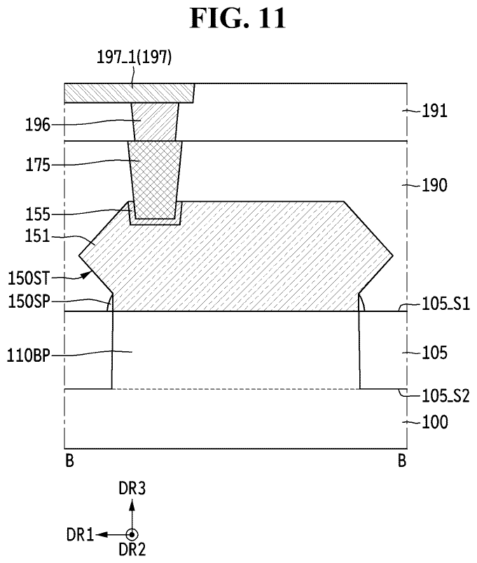

FIGS. 10 and 11 are diagrams illustrating an example of a semiconductor device. For convenience of description, differences thereof from those as described above with reference to FIGS. 1 to 3 will be mainly described. For reference, FIGS. 10 and 11 are cross-sectional views taken along lines A-A and B-B of FIG. 1, respectively.

Referring to FIGS. 10 and 11, in some implementations, the first epitaxial pattern structure 150ST may include a plurality of first epitaxial semiconductor patterns 150.

The second epitaxial pattern structure 250ST may include a plurality of second epitaxial semiconductor patterns 250. The third epitaxial pattern structure 350ST may include at least one third epitaxial semiconductor pattern 350.

The first epitaxial semiconductor pattern 150 and the second epitaxial semiconductor pattern 250 may be spaced apart from each other in the second direction DR2. The third epitaxial semiconductor pattern 350 may be disposed between the first epitaxial semiconductor pattern 150 and the second epitaxial semiconductor pattern 250. The third epitaxial semiconductor pattern 350 may be in contact with the first epitaxial semiconductor pattern 150 and the second epitaxial semiconductor pattern 250. For example, the third epitaxial semiconductor pattern 350 may be directly connected to the first epitaxial semiconductor pattern 150 and the second epitaxial semiconductor pattern 250.

The number of first epitaxial semiconductor patterns 150 included in the first epitaxial pattern structure 150ST may be greater than the number of third epitaxial semiconductor patterns 350 included in the third epitaxial pattern structure 350ST. The number of second epitaxial semiconductor patterns 250 included in the second epitaxial pattern structure 250ST may be greater than the number of third epitaxial semiconductor patterns 350 included in the third epitaxial pattern structure 350ST.

Although the first epitaxial pattern structure 150ST is illustrated as including two first epitaxial semiconductor patterns 150, this is intended only for convenience of illustration, and the pattern number is not limited thereto. Although the second epitaxial pattern structure 250ST is illustrated as including two second epitaxial semiconductor patterns 250, this is intended only for convenience of illustration, and the pattern number is not limited thereto. Although the third epitaxial pattern structure 350ST is illustrated as including one third epitaxial semiconductor pattern 350, this is intended only for convenience of illustration, and the pattern number is not limited thereto.

Each of the first epitaxial semiconductor patterns 150 included in the first epitaxial pattern structure 150ST may be connected to the first lower pattern 110BP. For example, one first epitaxial semiconductor pattern 150 may be disposed on one first lower pattern 110BP.

Each of the second epitaxial semiconductor patterns 250 included in the second epitaxial pattern structure 250ST may be connected to the second lower pattern 210BP. The third epitaxial semiconductor pattern 350 included in the third epitaxial pattern structure 350ST may be connected to the third lower pattern 310BP.

Each of the first epitaxial semiconductor pattern 150, the second epitaxial semiconductor pattern 250, and the third epitaxial semiconductor pattern 350 may include silicon or germanium, which is an elemental semiconductor material. As another example, each of the first epitaxial semiconductor pattern 150, the second epitaxial semiconductor pattern 250, and the third epitaxial semiconductor pattern 350 may include a compound semiconductor, and may include, for example, a group IV-IV compound semiconductor or a group III-V compound semiconductor.

Each of the first epitaxial semiconductor pattern 150 and the second epitaxial semiconductor pattern 250 contains impurities having a first conductivity type. The third epitaxial semiconductor pattern 350 contains impurities having a second conductivity type.

A first epitaxial spacer 150SP may be disposed on a sidewall of each of the first epitaxial semiconductor patterns 150. A second epitaxial spacer 250SP may be disposed on a sidewall of each second epitaxial semiconductor pattern 250. A third epitaxial spacer 350SP may be disposed on a sidewall of the third epitaxial semiconductor pattern 350.

The first epitaxial spacer 150SP, the second epitaxial spacer 250SP, and the third epitaxial spacer 350SP may be disposed on the first surface 105_S1 of the field insulating film. Each of the first epitaxial spacer 150SP, the second epitaxial spacer 250SP, and the third epitaxial spacer 350SP may include, for example, but is not limited to, silicon nitride, silicon oxynitride, silicon carbonitride, silicon oxycarbonitride, or a combination thereof.

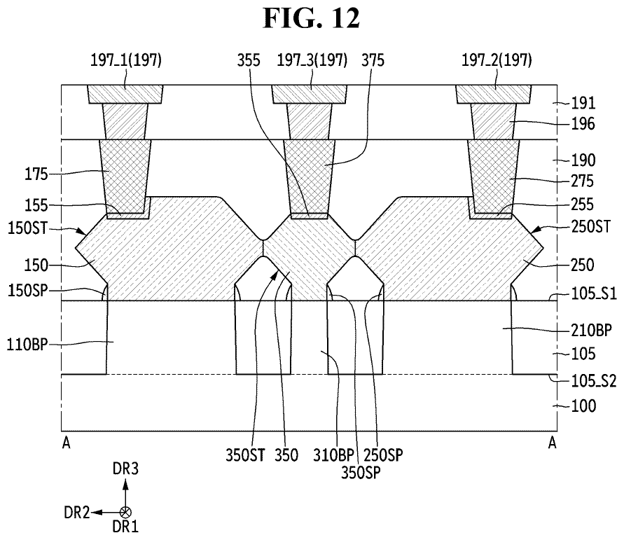

FIG. 12 is a diagram illustrating an example of a semiconductor device. For convenience of description, differences thereof from those as described above with reference to FIGS. 1 to 3, 10, and 11 will be mainly described.

Referring to FIG. 12, in some implementations, the number of third epitaxial semiconductor patterns 350 included in the third epitaxial pattern structure 350ST may be equal to the number of first epitaxial semiconductor patterns 150 included in the first epitaxial pattern structure 150ST, and may be equal to the number of first epitaxial semiconductor patterns 250 included in the second epitaxial pattern structure 250ST.

For example, each of the first epitaxial pattern structure 150ST, the second epitaxial pattern structure 250ST, and the third epitaxial pattern structure 350ST may include one epitaxial semiconductor pattern.

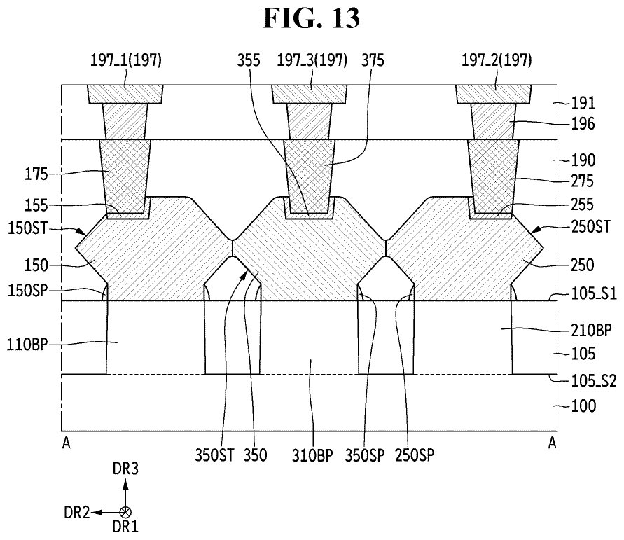

FIG. 13 is a diagram illustrating an example of a semiconductor device. For convenience of description, differences thereof from those as described above with reference to FIGS. 6 to 9 will be mainly described.

Referring to FIG. 13, in some implementations, the first to third epitaxial pattern structures 150ST, 250ST, and 350ST may include first to third epitaxial semiconductor patterns 150, 250, and 350, respectively.

The number of third epitaxial semiconductor patterns 350 included in the third epitaxial pattern structure 350ST may be equal to the number of first epitaxial semiconductor patterns 150 included in the first epitaxial pattern structure 150ST, and may be equal to the number of second epitaxial semiconductor patterns 250 included in the second epitaxial pattern structure 250ST. However, the pattern numbers are not limited thereto.

Although each of the first to third epitaxial pattern structures 150ST, 250ST, and 350ST is illustrated as including one epitaxial semiconductor pattern, in some implementations multiple epitaxial semiconductor patterns are included.

The concentration (/cm³) of the impurities of the first conductivity type contained in the first epitaxial semiconductor pattern 150 may be greater than the concentration of the impurities of the second conductivity type contained in the third epitaxial semiconductor pattern 350.

The concentration of the impurities of the first conductivity type contained in the second epitaxial semiconductor pattern 250 may be lower than the concentration of the impurities of the second conductivity type contained in the third epitaxial semiconductor pattern 350.

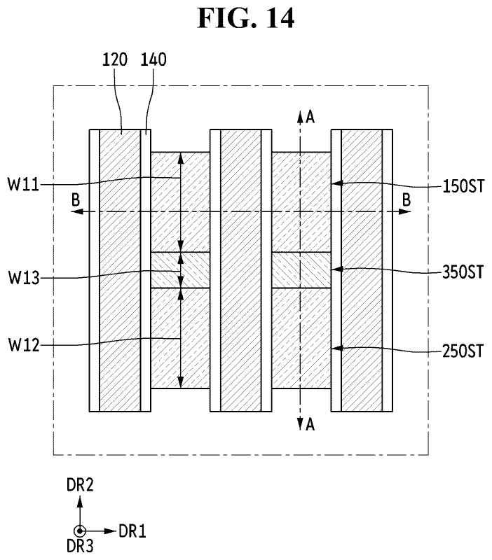

FIGS. 14 to 16 are diagrams illustrating an example of a semiconductor device. For convenience of description, differences thereof from those as described above with reference to FIGS. 1 to 3, 10, and 11 will be mainly described.

Referring to FIGS. 14 to 16, in some implementations, the semiconductor device includes a plurality of gate electrodes 120.

The plurality of gate electrodes 120 may be disposed on the field insulating film 105. For example, the plurality of gate electrodes 120 may be disposed on the first surface 105_S1 of the field insulating film. Each gate electrode 120 may extend in the second direction DR2. The gate electrodes 120 may be spaced apart from each other in the first direction DR1. The gate electrodes 120 may be adjacent to each other in the first direction DR1.

The plurality of gate electrodes 120 may be disposed on each of the first lower pattern 110BP, the second lower pattern 210BP, and the third lower pattern 310BP. Each of the first lower pattern 110BP, the second lower pattern 210BP, and the third lower pattern 310BP may intersect the plurality of gate electrodes 120.

The gate electrode 120 may include at least one of a metal, a conductive metal nitride, a metal silicide, a doped semiconductor material, a conductive metal oxide, or a conductive metal oxynitride. The gate electrode 120 may be made of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. However, the materials within the scope of this disclosure are not limited thereto. The conductive metal oxide and the conductive metal oxynitride referred to above may include oxidized products of the above-mentioned materials. However, such materials are not limited thereto.

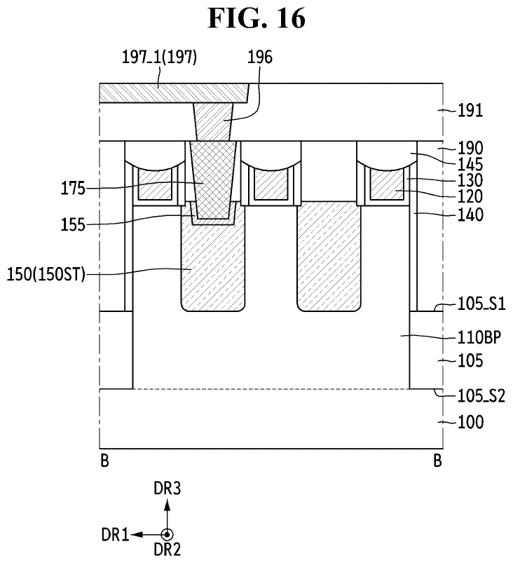

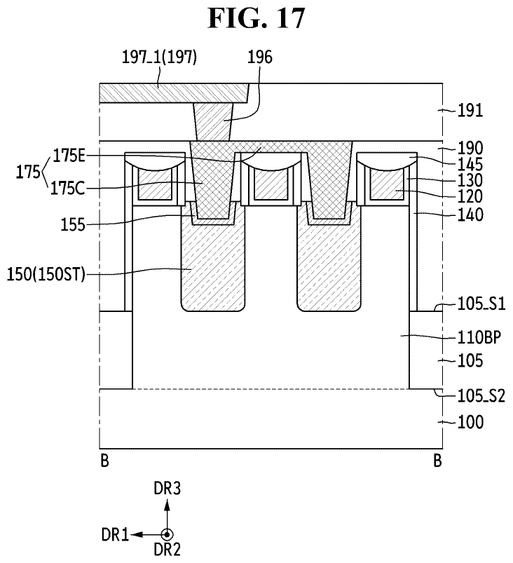

A gate insulating film 130 may be disposed between the gate electrode 120 and the first lower pattern 110BP. Similar to the configuration illustrated for the first lower pattern 110BP in FIGS. 16 and 17, the gate insulating film 130 may be disposed between the gate electrode 120 and the second lower pattern 210BP and between the gate electrode 120 and the third lower pattern 310BP.

The gate insulating film 130 may include silicon oxide, silicon-germanium oxide, germanium oxide, silicon oxynitride, silicon nitride, or a high-k material having a higher dielectric constant than that of silicon oxide. The high dielectric constant (high-k) material may i nclude at least one of, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate. Although the gate insulating film 130 is illustrated as a single film, this is intended only for convenience of illustration, and the gate insulating film 130 may include multiple films/layers.

In some implementation, the semiconductor device may include an NC (negative capacitance) FET using a negative capacitor. For example, the gate insulating film 130 may include a ferroelectric material film having ferroelectric properties and a paraelectric material film having paraelectric properties.

The ferroelectric material film may have negative capacitance, and the paraelectric material film may have positive capacitance. For example, when two or more capacitors may be connected in series to each other, and capacitance of each of the capacitors has a positive value, a total capacitance is smaller than capacitance of each individual capacitor. On the other hand, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, or lead zirconium titanium oxide. Hafnium zirconium oxide may refer to a material obtained by doping hafnium oxide with zirconium (Zr). As another example, hafnium zirconium oxide may refer to a compound of hafnium (Hf), zirconium (Zr), and oxygen (O).

The ferroelectric material film may further contain doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) or tin (Sn). A type of the dopant contained in the ferroelectric material film may vary depending on a type of the ferroelectric material included in the ferroelectric material film.

When the ferroelectric material film includes hafnium oxide, the dopant contained in the ferroelectric material film may include, for example, at least one of gadolinium (Gd), silicon (Si), zirconium (Zr), aluminum (Al), or yttrium (Y).

When the dopant is aluminum (Al), the ferroelectric material film may contain about 3 to about 8 at% (atomic %) of aluminum. The content of the dopant may be a content of aluminum based on a sum of hafnium and aluminum.

When the dopant is silicon (Si), the ferroelectric material film may contain about 2 to about 10 at % of silicon. When the dopant is yttrium (Y), the ferroelectric material film may contain about 2 to about 10 at % yttrium. When the dopant is gadolinium (Gd), the ferroelectric material film may contain about 1 to about 7 at % gadolinium. When the dopant is zirconium (Zr), the ferroelectric material film may contain about 50 to about 80 at % zirconium.

The paraelectric material film may have paraelectric properties. The paraelectric material film may include, for example, at least one of silicon oxide or metal oxide having a high dielectric constant. The metal oxide contained in the paraelectric material film may include, for example, at least one of hafnium oxide, zirconium oxide or aluminum oxide. However, the material is not limited thereto.

The ferroelectric material film and the paraelectric material film may include the same material. The ferroelectric material film may have ferroelectric properties, and the paraelectric material film may not have the ferroelectric properties. For example, when each of the ferroelectric material film and the paraelectric material film includes hafnium oxide, a crystal structure of hafnium oxide contained in the ferroelectric material film is different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 to about 10 nm, the thickness is not limited thereto. Because a critical thickness exhibiting the ferroelectric properties may vary based on a type of the ferroelectric material, the thickness of the ferroelectric material film may vary depending on the type of the ferroelectric material.

In some implementations, the gate insulating film 130 may include one ferroelectric material film. In some implementations, the gate insulating film 130 may include a plurality of ferroelectric material films spaced apart from each other. The gate insulating film 130 may have a multilayer structure in which a plurality of ferroelectric material films and a plurality of paraelectric material films are alternately laminated.

A gate spacer 140 may be disposed on a sidewall of the gate electrode 120. The gate spacer 140 may include, for example, silicon nitride, silicon oxynitride, silicon oxide, silicon oxycarbonitride, silicon boron nitride, silicon oxyboron nitride, silicon oxycarbide, or a combination thereof.

A gate capping pattern 145 may be disposed on the gate electrode 120 and the gate spacer 140. The gate capping pattern 145 may be disposed on an upper surface of the gate electrode 120. In some implementations, the gate capping pattern 145 may be disposed between the gate spacers 140. The gate capping pattern 145 may include, for example, silicon nitride, silicon oxynitride, silicon carbonitride, silicon oxycarbonitride, or a combination thereof.

In some implementations, the gate capping pattern 145 may not be disposed on the gate electrode 120.

Each of the first epitaxial pattern structure 150ST, the second epitaxial pattern structure 250ST, and the third epitaxial pattern structure 350ST may be disposed between the gate electrodes 120 adjacent to each other in the first direction DR1.

Between the gate electrodes 120 adjacent to each other in the first direction DR1, the width W11 in the second direction DR2 of the first epitaxial pattern structure 150ST may be greater than the width W13 in the second direction DR2 of the third epitaxial pattern structure 350ST. Between the gate electrodes 120 adjacent to each other in the first direction DR1, the width W12 in the second direction DR2 of the second epitaxial pattern structure 250ST may be greater than the width W13 in the second direction DR2 of the third epitaxial pattern structure 350ST.

There may be three or more gate electrodes 120 intersecting each of the first lower pattern 110BP, the second lower pattern 210BP, and the third lower pattern 310BP. The plurality of first epitaxial pattern structures 150ST may be disposed on the first lower pattern 110BP. The plurality of second epitaxial pattern structures 250ST may be disposed on the second lower pattern 210BP, and the plurality of third epitaxial pattern structures 350ST may be disposed on the third lower pattern 310BP. The first epitaxial pattern structures 150ST may be arranged in the first direction DR1. The second epitaxial pattern structures 250ST may be arranged in the first direction DR1. The third epitaxial pattern structures 350ST may be arranged in the first direction DR1.

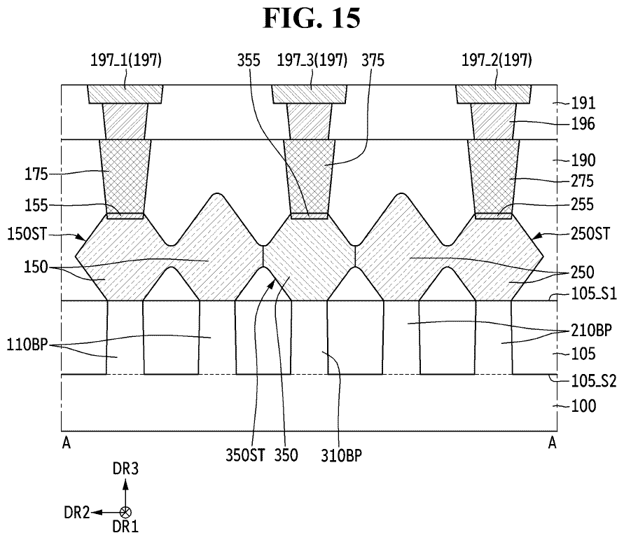

In FIGS. 14 and 15, the first epitaxial pattern structure 150ST between the gate electrodes 120 includes a plurality of first epitaxial semiconductor patterns 150. The second epitaxial pattern structure 250ST between the gate electrodes 120 includes a plurality of second epitaxial semiconductor patterns 250. In some implementations, with a configuration as illustrated in FIG. 12, each of the first epitaxial pattern structure 150ST and the second epitaxial pattern structure 250ST between the gate electrodes 120 may include one epitaxial semiconductor pattern.

As shown in FIG. 16, there may be three or more gate electrodes 120 intersecting the first lower pattern 110BP. The plurality of first epitaxial semiconductor patterns 150 may be disposed on one first lower pattern 110BP. Each of the first epitaxial semiconductor patterns 150 may be disposed between the gate electrodes 120 adjacent to each other in the first direction DR1. When the plurality of first epitaxial pattern structures 150ST disposed on the first lower pattern 110BP include a first sub-epitaxial pattern structure and a second sub-epitaxial pattern structure, the plurality of first epitaxial semiconductor patterns 150 disposed on one first lower pattern 110BP may include one of the first epitaxial semiconductor patterns 150 included in the first sub-epitaxial pattern structure and one of the first epitaxial semiconductor patterns 150 included in the second sub-epitaxial pattern structure.

Correspondingly, a plurality of second epitaxial semiconductor patterns 250 may be disposed on one second lower pattern 210BP. A plurality of third epitaxial semiconductor patterns 350 may be disposed on one third lower pattern 310BP.

Hereinafter, a case in which three or more gate electrodes 120 intersect each of the first lower pattern 110BP, the second lower pattern 210BP, and the third lower pattern 310BP will be described.

The first front connection contact 175 may be connected to one first epitaxial pattern structure 150ST among the plurality of first epitaxial pattern structures 150ST disposed on the first lower pattern 110BP.

The second front connection contact 275 may be connected to one second epitaxial pattern structure 250ST among the plurality of second epitaxial pattern structures 250ST, and the third front connection contact 375 may be connected to one third epitaxial pattern structure 250ST among the plurality of third epitaxial pattern structures 350ST.

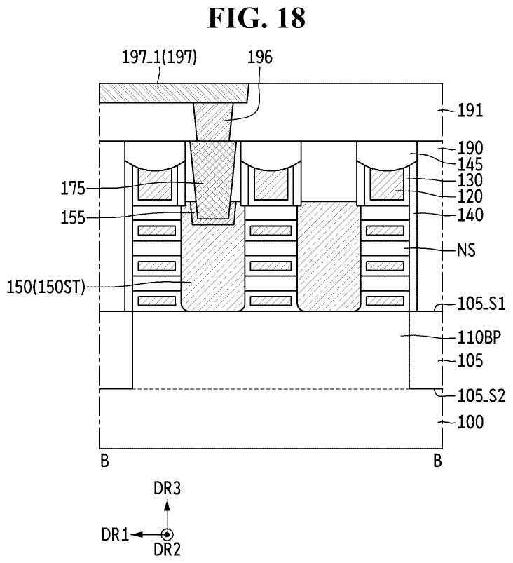

FIGS. 17, 18, and 18 are diagrams illustrating examples of semiconductor devices. For convenience of description, differences thereof from those as described above with reference to FIGS. 14 to 16 will be mainly described.

Referring to FIG. 17, in some implementations, the first front connection contact 175 may be connected to the plurality of first epitaxial pattern structures 150ST disposed on the first lower pattern 110BP.

The first epitaxial pattern structures 150ST adjacent to each other in the first direction DR1 with the gate electrode 120 interposed therebetween may be connected to each other. For example, the first front connection contact 175 may be connected to two or more first epitaxial pattern structures 150ST.

The first front connection contact 175 may include an extension portion 175E and a plurality of connection portions 175C. The connection portions 175C of the first front connection contact may be connected to the first epitaxial pattern structures 150ST, respectively. The extension portion 175E of the first front connection contact may connect the plurality of connection portions 175C of the first front connection contact to each other. The front wiring via 196 may be connected to the extension portion 175E of the first front connection contact.

Correspondingly, the second front connection contact 275 may be connected to the plurality of second epitaxial pattern structures 250ST, and the third front connection contact 375 may be connected to the plurality of third epitaxial pattern structures 350ST. A shape of each of the second front connection contact 275 and the third front connection contact 375 may be similar to a shape of the first front connection contact 175.

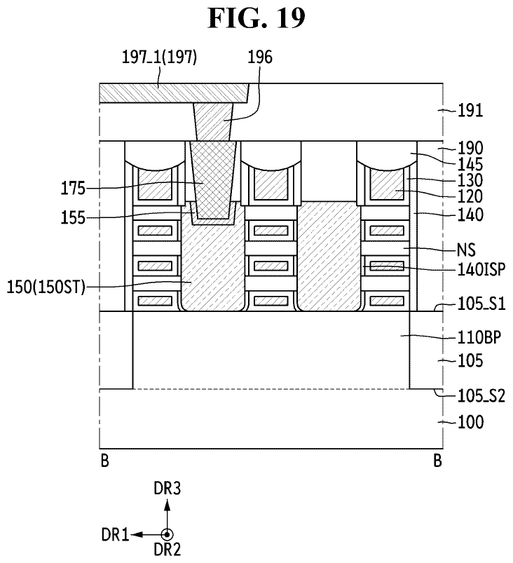

Referring to FIGS. 18 and 19, in some implementations, the semiconductor device includes a plurality of first sheet patterns NS.

The plurality of first sheet patterns NS may be disposed on the first surface 105_S1 of the field insulating film. For example, the plurality of first sheet patterns NS may be disposed on the first lower pattern 110BP. Each of the first sheet patterns NS may be spaced apart from the first lower pattern 110BP in the third direction DR3. The first sheet patterns NS may be spaced apart from each other in the third direction DR3.

A portion of the gate electrode 120 and a portion of the gate insulating film 130 may be disposed between the first sheet patterns NS adjacent to each other in the third direction DR3 and between the first lower pattern 110BP and the first sheet pattern NS. In some implementations, in a cross-sectional view in which the gate electrode 120 is cut along the second direction DR2, the gate electrode 120 and the gate insulating film 130 may surround the first sheet pattern NS.

In some implementations, with a configuration similar to that illustrated in FIG. 18 or 19, second sheet patterns and third sheet patterns may be disposed on the second lower pattern 210BP and the third lower pattern 310BP, respectively.

The first sheet pattern NS may include one of silicon or germanium as element semiconductor materials, a group IV-IV compound semiconductor, or a group III-V compound semiconductor.

The first epitaxial pattern structure 150ST may be connected to the first sheet patterns NS. Further, the second epitaxial pattern structure (250ST of FIG. 15) may be connected to the second sheet patterns, and the third epitaxial pattern structure (350ST of FIG. 15) may be connected to the third sheet patterns.

In FIG. 18, a portion of the gate electrode 120 and a portion of the gate insulating film 130 between the first sheet patterns NS adjacent in the third direction DR3 may be in contact with the first epitaxial pattern structure 150ST.

In FIG. 19, a portion of the gate electrode 120 and a portion of the gate insulating film 130 between the first sheet patterns NS adjacent in the third direction DR3 may not contact the first epitaxial pattern structure 150ST. An inner spacer 140ISP may be disposed between the first sheet patterns NS adjacent to each other in the third direction DR3 and between the first lower pattern 110BP and the first sheet pattern NS. The inner spacer 140ISP may include an insulating material.

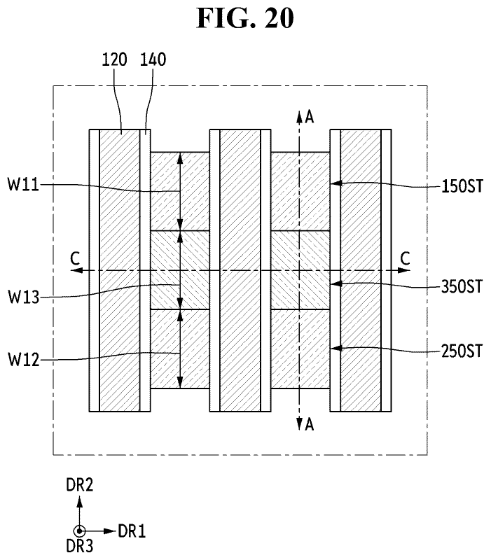

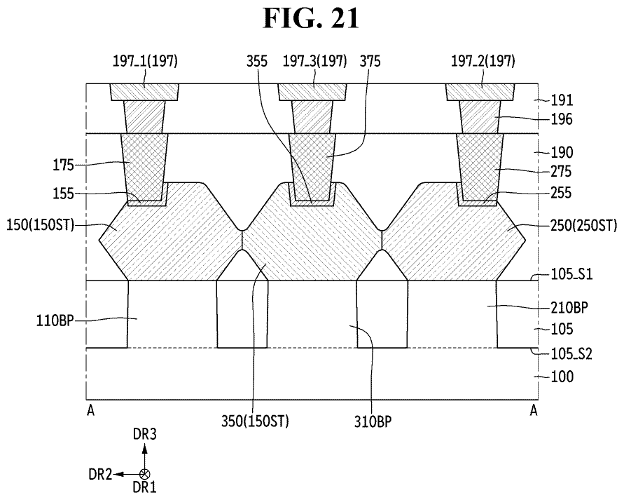

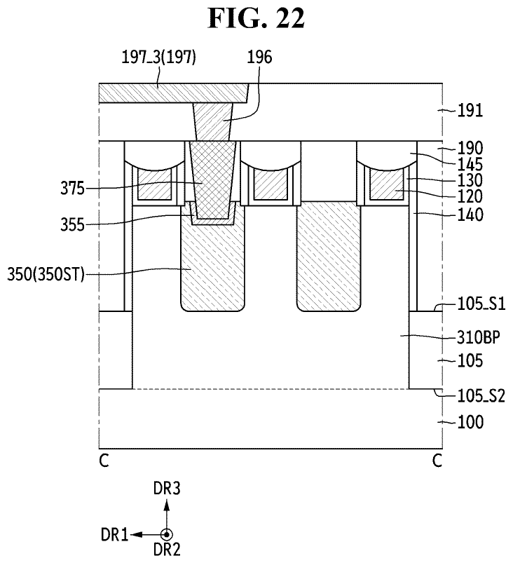

FIGS. 20 to 22 are diagrams illustrating an example of a semiconductor device. For convenience of description, differences thereof from those as described above with reference to FIGS. 14 to 17 will be mainly described.

For reference, a cross-sectional view taken along a line B-B of FIG. 20 may be the same as that of FIG. 17. In addition, in FIG. 20, a cross-sectional view of the second epitaxial pattern structure 250ST taken along the first direction DR1 may be similar to that of FIG. 17. However, the scope of tis disclosure is not limited thereto.

Referring to FIGS. 20 to 22, in some implementations, the first to third epitaxial pattern structures 150ST, 250ST, and 350ST may include first to third epitaxial semiconductor patterns 150, 250, and 350, respectively.

The number of first epitaxial semiconductor patterns 150 connected to the first front connection contact 175 may be equal to the number of third epitaxial semiconductor patterns 350 connected to the third connection contact 375.

The number of second epitaxial semiconductor patterns 250 connected to the second front connection contact 275 may be equal to the number of third epitaxial semiconductor patterns 350 connected to the third connection contact 375. However, the pattern numbers are not limited thereto.

Between the adjacent gate electrodes 120, the width W11 in the second direction DR2 of the first epitaxial pattern structure 150ST may be equal to the width W13 in the second direction DR2 of the third epitaxial pattern structure 350ST. However, the widths are not limited thereto. Between the adjacent gate electrodes 120, the width W12 in the second direction DR2 of the second epitaxial pattern structure 250ST may be equal to the width W13 in the second direction DR2 of the third epitaxial pattern structure 350ST. However, the widths are not limited thereto.

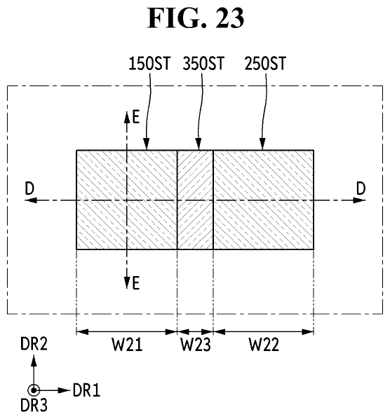

FIGS. 23 to 25 are diagrams illustrating an example of a semiconductor device. For reference, differences thereof from those as described above with reference to FIGS. 1 to 3, 10, and 11 will be mainly described.

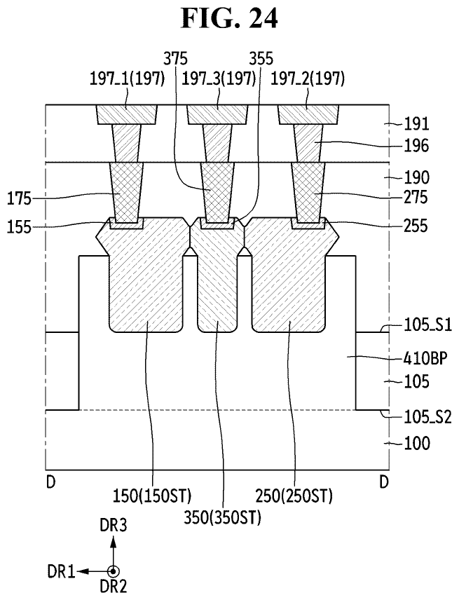

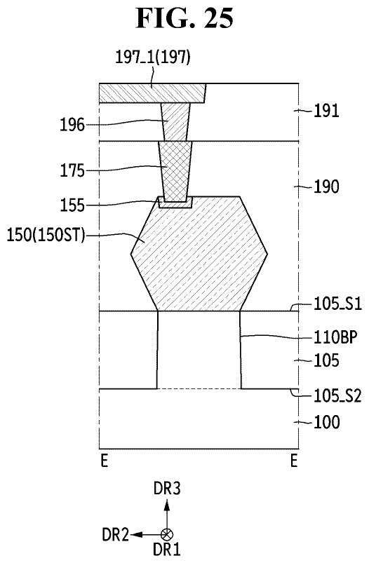

For reference, FIG. 23 is a plan view, FIG. 24 is a cross-sectional view taken along a line D-D of FIG. 23, and FIG. 25 is a cross-sectional view taken along a line E-E of FIG. 23.

Referring to FIGS. 23 to 25, in some implementations, the semiconductor device includes a fourth lower pattern 410BP.

The fourth lower pattern 410BP may be disposed on the substrate 100. The fourth lower pattern 410BP may protrude in the third direction DR3. The fourth lower pattern 410BP may extend in the first direction DR. 1.

Each of the first epitaxial pattern structure 150ST, the second epitaxial pattern structure 250ST, and the third epitaxial pattern structure 350ST may be disposed on the fourth lower pattern 410BP. Each of the first epitaxial pattern structure 150ST, the second epitaxial pattern structure 250ST, and the third epitaxial pattern structure 350ST may be in contact with the fourth lower pattern 410BP.

A portion of the first epitaxial semiconductor pattern 150 may be disposed in the fourth lower pattern 410BP. The remainder of the first epitaxial semiconductor pattern 150 may protrude in the third direction DR3 beyond an upper surface of the fourth lower pattern 410BP.

A portion of the second epitaxial semiconductor pattern 250 may be disposed in the fourth lower pattern 410BP. The remainder of the second epitaxial semiconductor pattern 250 may protrude in the third direction DR3 beyond the upper surface of the fourth lower pattern 410BP. The second epitaxial pattern structure 250ST may be spaced apart from the first epitaxial pattern structure 150ST in the second direction DR2.

A portion of the third epitaxial semiconductor pattern 350 may be disposed in the fourth lower pattern 410BP. The remainder of the third epitaxial semiconductor pattern 350 may protrude in the third direction DR3 beyond the upper surface of the fourth lower pattern 410BP. The third epitaxial pattern structure 350ST may be disposed between the first epitaxial pattern structure 150ST and the second epitaxial pattern structure 250ST.

The first epitaxial pattern structure 150ST, the second epitaxial pattern structure 250ST, and the third epitaxial pattern structure 350ST may be aligned with each other in the first direction DR1. The portion of the third epitaxial semiconductor pattern 350 protruding beyond the upper surface of the fourth lower pattern 410BP may be in contact with the portion of the first epitaxial semiconductor pattern 150 and the portion of the second epitaxial semiconductor pattern 350 protruding beyond the upper surface of the fourth lower pattern 410BP.

Each of the first to third epitaxial pattern structures 150ST, 250ST, and 350ST may include each of the first to third epitaxial semiconductor patterns 150, 250, and 350.

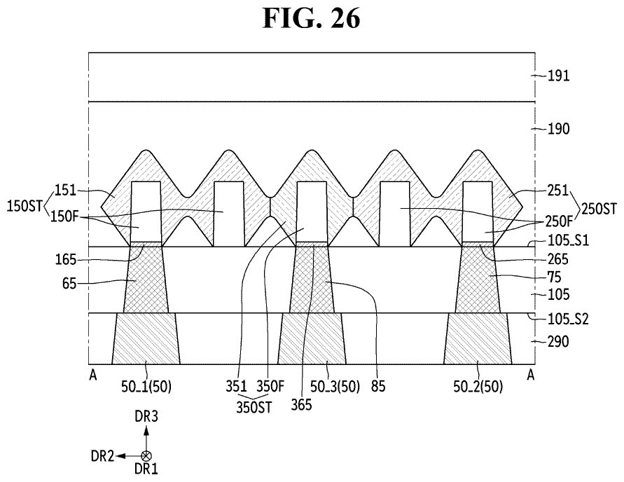

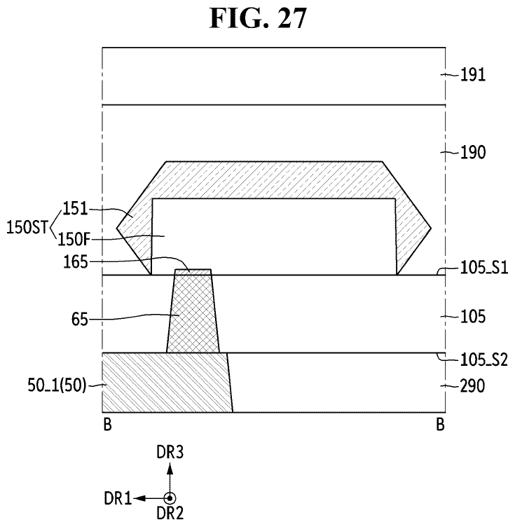

FIGS. 26 and 27 are diagrams illustrating an example of a semiconductor device. For convenience of description, differences thereof from those as described above with reference to FIGS. 1 to 3 will be mainly described.

Referring to FIGS. 26 and 27, the semiconductor device may include the field insulating film 105, the first epitaxial pattern structure 150ST, the second epitaxial pattern structure 250ST, the third epitaxial pattern structure 350ST, a first back connection contact 65, a second back connection contact 75, a third back connection contact 85, and a back wiring line 50.

The first back connection contact 65 may be disposed in the field insulating film 105. The first back connection contact 65 is connected to the first epitaxial pattern structure 150ST.

The second back connection contact 75 may be disposed in the field insulating film 105. The second back connection contact 75 is connected to the second epitaxial pattern structure 250ST.

The third back connection contact 85 may be disposed in the field insulating film 105. The third back connection contact 85 is connected to the third epitaxial pattern structure 350ST.

Although each of the first back connection contact 65, the second back connection contact 75, and the third back connection contact 85 is illustrated as a single film, this is intended only for convenience of illustration, and the contacts 65, 75, 85 may include multiple films. Each of the first back connection contact 65, the second back connection contact 75, and the third back connection contact 85 may include, for example, a metal, a conductive metal nitride, a conductive metal carbide, a conductive metal oxide, a conductive metal carbonitride, a two-dimensional (2D) material, or a combination thereof.

A first back contact silicide film 165 may be disposed between the first back connection contact 65 and the first epitaxial pattern structure 150ST. A second back contact silicide film 265 may be disposed between the second back connection contact 75 and the second epitaxial pattern structure 250ST. A third back contact silicide film 365 may be disposed between the third back connection contact 85 and the third epitaxial pattern structure 350ST. Each of the first back contact silicide film 165, the second back contact silicide film 265, and the third back contact silicide film 365 may include a metal silicide.

A back interlayer insulating film 290 may be disposed on the field insulating film 105. The back interlayer insulating film 290 may be disposed on the second surface 105_S2 of the field insulating film. The back interlayer insulating film 290 may include, but is not limited to, at least one of silicon oxide, silicon nitride, or silicon oxynitride. When the back interlayer insulating film 290 and the field insulating film 105 include the same material, a boundary between the back interlayer insulating film 290 and the field insulating film 105 may not be defined by material. In this case, the boundary between the back interlayer insulating film 290 and the field insulating film 105 may be defined using the lowermost portion of each of the first back connection contact 65, the second back connection contact 75, and the third back connection contact 85.

The back wiring line 50 may be disposed in the back interlayer insulating film 290. The back wiring line 50 may include first to third back wiring lines 50_1, 50_2, and 50_3.

The first back wiring line 50_1 may be connected to the first back connection contact 65. The second back wiring line 50_2 may be connected to the second back connection contact 75. The third back wiring line 50_3 may be connected to the third back connection contact 85.

The back wiring line 50 may include a line portion and a via portion. The first back wiring line 50_1 will be described by way of example. A line portion of the first back wiring line 50_1 may extend in an elongate manner in the first direction DR1. A via portion of the first back wiring line 50_ 1 may protrude from the line portion of the first back wiring line 50_ 1 in the third direction DR3. The via portion of the first back wiring line 50_1 may protrude toward the first back connection contact 65.

Although the back wiring line 50 is illustrated as a single film, this is intended only for convenience of illustration, and the back wiring line 50 may include multiple films. Each of the back wiring lines 50 may include, for example, at least one of a metal, a conductive metal nitride, a conductive metal carbide, a conductive metal oxide, a conductive metal carbonitride, or a two-dimensional material (2D material).

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure as set forth in the following claims.

What is claimed is:

1. A semiconductor device comprising:
a field insulating film including a first surface and a second surface facing opposing one other in a first direction;
a first epitaxial pattern structure on the first surface of the field insulating film and having a first conductivity type;
a second epitaxial pattern structure spaced apart from the first epitaxial pattern structure in a second direction perpendicular to the first direction and having the first conductivity type;
a third epitaxial pattern structure between the first epitaxial pattern structure and the second epitaxial pattern structure along the second direction and having a second conductivity type different from the first conductivity type;
a first contact electrically connected to the first epitaxial pattern structure;
a second contact electrically connected to the second epitaxial pattern structure; and
a third contact electrically connected to the third epitaxial pattern structure,
wherein the third epitaxial pattern structure is in contact with the first epitaxial pattern structure and the second epitaxial pattern structure.

2. The semiconductor device of claim 1, wherein a width in the second direction of the third epitaxial pattern structure is smaller than a width in the second direction of the first epitaxial pattern structure, and
wherein the width in the second direction of the third epitaxial pattern structure is smaller than a width in the second direction of the second epitaxial pattern structure.

3. The semiconductor device of claim 2, wherein each of the first to third epitaxial pattern structures includes a single epitaxial semiconductor pattern.

4. The semiconductor device of claim 2, wherein a number of first epitaxial semiconductor patterns included in the first epitaxial pattern structure is greater than a number of third epitaxial semiconductor patterns included in the third epitaxial pattern structure,
wherein a number of second epitaxial semiconductor patterns included in the second epitaxial pattern structure is greater than the number of the third epitaxial semiconductor patterns included in the third epitaxial pattern structure.

5. The semiconductor device of claim 1, wherein a width in a third direction of the third epitaxial pattern structure is smaller than a width in the third direction of the first epitaxial pattern structure,
wherein the width in the third direction of the third epitaxial pattern structure is smaller than a width in the third direction of the second epitaxial pattern structure, and
wherein each of the first direction and the second direction is perpendicular to the third direction.

6. The semiconductor device of claim 1, wherein each of the first epitaxial pattern structure and the second epitaxial pattern structure comprises first impurities having the first conductivity type,
wherein the third epitaxial pattern structure comprises second impurities having the second conductivity type,
wherein a concentration of the first impurities in the first epitaxial pattern structure is greater than a concentration of the second impurities in the third epitaxial pattern structure, and
wherein a concentration of the first impurities in the second epitaxial pattern structure is lower than the concentration of the second impurities in the third epitaxial pattern structure.

7. The semiconductor device of claim 1, further comprising a first lower pattern, a second lower pattern, and a third lower pattern spaced apart from each other in the second direction,
wherein the field insulating film covers a sidewall of the first lower pattern, a sidewall of the second lower pattern, and a sidewall of the third lower pattern,
wherein the first epitaxial pattern structure is in contact with the first lower pattern,
wherein the second epitaxial pattern structure is in contact with the second lower pattern, and
wherein the third epitaxial pattern structure is in contact with the third lower pattern.

8. The semiconductor device of claim 1, further comprising a lower pattern extending in the second direction,
wherein each of the first epitaxial pattern structure, the second epitaxial pattern structure, and the third epitaxial pattern structure is in contact with the lower pattern, and
wherein the lower pattern comprises a semiconductor.

9. The semiconductor device of claim 1, comprising a front wiring line on the first surface of the field insulating film,
wherein each of the first to third contacts is electrically connected to the front wiring line.

10. The semiconductor device of claim 1, further comprising a back wiring line on the second surface of the field insulating film,
wherein each of the first to third contacts is electrically connected to the back wiring line.

11. The semiconductor device of claim 1, wherein the first epitaxial pattern structure includes a fin-shaped pattern portion and an epitaxially-grown portion,
wherein the epitaxially-grown portion is disposed on a sidewall of the fin-shaped pattern portion and is in contact with the fin-shaped pattern portion.

12. A semiconductor device comprising:
a field insulating film including a first surface and a second surface opposing one another along a first direction;
a first epitaxial pattern structure on the first surface of the field insulating film and having a first conductivity type;
a second epitaxial pattern structure spaced apart from the first epitaxial pattern structure in a second direction perpendicular to the first direction and having the first conductivity type;
a third epitaxial pattern structure between the first epitaxial pattern structure and the second epitaxial pattern structure in the second direction and having a second conductivity type different from the first conductivity type;
a first contact electrically connected to the first epitaxial pattern structure;
a second contact electrically connected to the second epitaxial pattern structure; and
a third contact electrically connected to the third epitaxial pattern structure,
wherein each of the first to third epitaxial pattern structures includes a fin-shaped pattern portion and an epitaxially-grown portion,
wherein the fin-shaped pattern portion of the third epitaxial pattern structure is spaced apart from the fin-shaped pattern portion of the first epitaxial pattern structure and the fin-shaped pattern portion of the second epitaxial pattern structure in the second direction, and
wherein the epitaxially-grown portion of the third epitaxial pattern structure is in contact with the epitaxially-grown portion of the first epitaxial pattern structure and the epitaxially-grown portion of the second epitaxial pattern structure.

13. The semiconductor device of claim 12, wherein a width in the second direction of the third epitaxial pattern structure is smaller than a width in the second direction of the first epitaxial pattern structure, and
wherein the width in the second direction of the third epitaxial pattern structure is smaller than a width in the second direction of the second epitaxial pattern structure.

14. The semiconductor device of claim 12, wherein a width in a third direction of the third epitaxial pattern structure is smaller than a width in the third direction of the first epitaxial pattern structure,
wherein the width in the third direction of the third epitaxial pattern structure is smaller than a width in the third direction of the second epitaxial pattern structure, and
wherein each of the first direction and the second direction is perpendicular to the third direction.

15. The semiconductor device of claim 12, wherein each of the first epitaxial pattern structure and the second epitaxial pattern structure comprises first impurities having the first conductivity type,
wherein the third epitaxial pattern structure comprises second impurities having the second conductivity type,
wherein a concentration of the first impurities in the first epitaxial pattern structure is greater than a concentration of the second impurities in the third epitaxial pattern structure,
wherein a concentration of the first impurities in the second epitaxial pattern structure is lower than the concentration of the second impurities in the third epitaxial pattern structure.

16. The semiconductor device of claim 12, comprising a front wiring line on the first surface of the field insulating film,
wherein each of the first to third contacts is electrically connected to the front wiring line.

17. The semiconductor device of claim 12, comprising a back wiring line on the second surface of the field insulating film,
wherein each of the first to third contacts is electrically connected to the back wiring line.

18. A semiconductor device comprising:
a back wiring line including a first surface and a second surface opposing one another along a first direction;
a first epitaxial pattern structure on the first surface of the back wiring line and having a first conductivity type;
a second epitaxial pattern structure spaced apart from the first epitaxial pattern structure in a second direction perpendicular to the first direction and having the first conductivity type;
a third epitaxial pattern structure between the first epitaxial pattern structure and the second epitaxial pattern structure in the second direction and having a second conductivity type different from the first conductivity type;
a field insulating film between the back wiring line and the first epitaxial pattern structure;
a first contact in the field insulating film and electrically connected to the first epitaxial pattern structure;
a second contact in the field insulating film and electrically connected to the second epitaxial pattern structure; and
a third contact in the field insulating film and electrically connected to the third epitaxial pattern structure,
wherein the third epitaxial pattern structure is in contact with the first epitaxial pattern structure and the second epitaxial pattern structure.

19. The semiconductor device of claim 18, wherein a width in the second direction of the third epitaxial pattern structure is smaller than a width in the second direction of the first epitaxial pattern structure, and
wherein the width in the second direction of the third epitaxial pattern structure is smaller than a width in the second direction of the second epitaxial pattern structure.

20. The semiconductor device of claim 18, wherein a width in a third direction of the third epitaxial pattern structure is smaller than a width in the third direction of the first epitaxial pattern structure,
wherein the width in the third direction of the third epitaxial pattern structure is smaller than a width in the third direction of the second epitaxial pattern structure, and
wherein each of the first direction and the second direction is perpendicular to the third direction.
